(19) United States
(12) Patent Application Publication
(10) Pub. No.: US 2026/0060136 A1
(43) Pub. Date: Feb. 26, 2026

(54) Power Electronics Device and Plug Connector Assembly Having an Electrically Insulative Compressible Body

(71) Applicant: Infineon Technologies AG, Neubiberg (DE)

(72) Inventors: Georg Troska, Fröndenberg (DE); Tamás Gurnyik, Mogyoród (HU)

(21) Appl. No.: 18/810,569

(22) Filed: Aug. 21, 2024

(51) Int. Cl. H01L 23/10; H01R 13/52

(52) U.S. Cl. CPC H01L 23/10; H01R 13/5219

(57) ABSTRACT

A power electronics device includes one or more power semiconductor dies within a housing, a plurality of terminals electrically connected to the one or more power semiconductor dies, and a compressible body. Each terminal has a contact end exposed at a side of the housing. A first terminal is configured for a higher electric potential than other ones of the terminals. The compressible body is electrically insulative and disposed along at least one lateral side of the contact end of the first terminal. For an installed state of the power electronics device, the compressible body is configured to be under compression and span a gap between the side of the housing at which the contact end of the first terminal is exposed and a component to which the contact end of the first terminal is to be connected.

### BACKGROUND

Demand for electronic devices for power applications continues to increase rapidly across a wide range of industries, including automotive, consumer electronics, renewable energy, manufacturing, and medical, among many others. Developments in semiconductor materials such as silicon carbide (SiC) and gallium nitride (GaN) have enabled power electronics devices with advantageous features such as smaller footprint, higher voltage and current capabilities, and faster switching speeds.

Isolation between terminals configured for different potentials must be considered when designing a power electronics device. Terminals having different potentials (e.g., a high potential and a low potential) that are placed too close to one another, for example, may risk dielectric breakdown leading to failure of the power electronics device. Thus, there are minimum design requirements for isolation that must be met when arranging terminals, and such requirements may inhibit the implementation of otherwise advantageous design features such as placing terminals closer to one another to reduce the size of the device and increasing terminal size for improved contact and/or higher current capability.

Two industry standard requirements that determine the minimum spacing between any two exposed metal contacts to prevent arcing through the air or along a surfaces are clearance and creepage. Clearance is the shortest distance between two metal contacts measured through the air. Creepage distance is the minimum distance between terminals or between a terminal and an external ground, such as a heatsink, along the surface of an insulation material. Current solutions for improving creepage and clearance are typically expensive, difficult to manufacture, place dimensional constraints on the power electronics device, and/or introduce other issues. Separating terminals by a greater distance, for example, may be acceptable in some applications but may exceed dimensional constraints in others, and may also result in parasitic inductances that affect other performance characteristics such as switching speeds. Features such as fins and/or protrusions that are structured into the device housing between terminals may improve creepage but may also increase manufacturing complexity and/or cost. This solution may also require corresponding features for increasing the creepage distance on a corresponding assembly or component to which the power electronics device is attached (e.g., a module, a busbar) and, in some instances, requires coordination in designing the housing and assembly or component features to ensure proper alignment, further adding to the manufacturing complexity. Additionally, or alternatively, using a housing material having a high comparative tracking index (CTI) may improve creepage, however such materials are often expensive. Furthermore, neither solution involving the features nor the material of the housing reduces the impact of the cleanliness of the operating environment on the creepage and clearance distances, as the terminals are still exposed through air unless they are otherwise sealed from the outside environment.

Thus, there is a need for a cost-effective and simple to manufacture solution for reducing creepage in power electronics devices.

### SUMMARY

According to an embodiment of a power electronics device, the power electronics device comprises: a housing; one or more power semiconductor dies within the housing; a plurality of terminals electrically connected to the one or more power semiconductor dies and each having a contact end exposed at a side of the housing, wherein a first terminal is configured for a higher electric potential that other ones of the terminals; and a compressible body that is electrically insulative and disposed along at least one lateral side of the contact end of the first terminal, wherein for an installed state of the power electronics device, the compressible body is configured to be under compression and span a gap between the side of the housing at which the contact end of the first terminal is exposed and a component to which the contact end of the first terminal is to be connected.

According to an embodiment of a plug connector assembly, the plug connector assembly comprises: a connection end that comprises an electrically insulative housing that houses a first exposed electrical conductor configured for a first electric potential and a second exposed electrical conductor configured for a second electric potential different than the first electric potential; and a compressible body that is electrically insulative and attached to the electrically insulative housing, wherein for a mated state of the plug connector assembly, the compressible body is configured to be under compression and form a seal with an electrically insulative housing of another connection end such that, inside the mated connection ends, no creepage pathway is present between the first exposed electrical conductor and the second exposed electrical conductor.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a cross-sectional side view of a power electronics device, according to an embodiment.

FIG. 2 illustrates a cross-sectional side view of a power electronics device, according to an embodiment.

FIG. 3 illustrates a cross-sectional side view of a power electronics device, according to an embodiment.

FIG. 4 illustrates a cross-sectional side view of a power electronics device, according to an embodiment.

FIG. 5 illustrates a cross-sectional side view of a power electronics device, according to an embodiment.

FIG. 6 illustrates a cross-sectional side view of an assembly comprising a power electronics device attached to a busbar, according to an embodiment.

FIG. 7 illustrates a perspective view of a power electronics device, according to an embodiment.

FIG. 8 illustrates a perspective view of a plurality of compressible bodies, according to an embodiment.

FIG. 9 illustrates an exploded perspective view of an assembly, comprising a power electronics device and a pad comprising electrically insulative compressible sleeves, according to an embodiment.

FIG. 10 illustrates a side view of an assembly, comprising a power electronics device and a pad comprising electrically insulative compressible sleeves, according to an embodiment.

FIG. 11 illustrates a side view of electrically insulative compressible sleeves integrated into a pad, according to an embodiment.

FIG. 12 illustrates a side view of an electrically insulative compressible sleeve integrated into a pad, according to an embodiment.

FIG. 13 illustrates a perspective view of a power electronics device and electrically insulative compressible sleeves integrated into a pad, according to an embodiment.

FIGS. 14A and 14B illustrate side views of fitting electrically insulative compressible sleeves on pin-type terminals of a power electronics device, according to an embodiment.

FIG. 15 illustrates a perspective view of a power electronics device, according to an embodiment.

FIGS. 16A and 16B illustrate cross-sectional side views of a plug connector assembly and a mating plug connector assembly, according to an embodiment.

### DETAILED DESCRIPTION

Described herein are a power electronics device and a plug connector assembly each having a respective electrically insulative housing and including an electrically insulative compressible body.

In the example of the power electronics device, the compressible body may be a gasket, o-ring, sleeve, or other body that is disposed laterally along one or more sides of a contact end of a terminal exposed from a housing of the power electronics device. In various embodiments, the compressible body may surround one or more contact ends of the respective terminal, may be disposed between contact ends of adjacent terminals, or may be otherwise arranged such that part or all of the compressible body is disposed laterally between two or more contact ends of terminals on the surface of the housing. When the power electronics device is in an installed state, that is, attached to an assembly or component such as a module, printed circuit board, busbar, etc., the compressible body becomes compressed against the assembly or component and spans a gap between the surface of the housing of the power electronics device and the assembly or component to which the power electronics device is attached. In this installed state, the compressible body electrically and physically isolates the contact ends of the two or more terminals from the environment and from one another, and may entirely eliminate clearance and/or creepage pathways between the respective contact ends of terminals that are configured for different electrical potentials (e.g., creepage between high potential and low potential terminals).

In the example of the plug connector assembly, the electrically insulative housing houses a first exposed electrical conductor configured for a first electric potential and a second exposed electrical conductor configured for a second electric potential different than the first electric potential. The compressible body is attached to the housing such that when the plug connector is in a mated state, that is, when the housing and the electrical conductors are mated with a housing and electrical conductors of a corresponding plug connector assembly, the compressible body is under compression and forms a seal with the housing of the corresponding plug connector assembly. In this mated state, the compressible body electrically and physically isolates the first and second exposed electrical conductors of the plug connector assembly from one another and from the outside environment, potentially eliminating creepage pathways along the housing of the plug connector assembly and the housing of the corresponding plug connector assembly, and clearance pathways through air between the first and second electrical conductors.

Utilizing a compressible body to eliminate creepage pathways and/or clearance pathways between adjacent contact ends of terminals of a power electronics device and adjacent exposed electrical conductors of a plug connector assembly as described herein may negate the need for complex features on the housing and/or on a corresponding assembly or component and may enable the use of cheaper materials for the housing. Additionally, in some embodiments, e.g., when using a gasket or o-ring and in the example of the plug connector assembly, the compressible body may seal the contact end of a terminal (e.g., of a power electronics device) or an exposed conductor (e.g., of the plug connector assembly) from the external environment and may thus reduce the impact of the cleanliness of the operating environment on creepage and/or clearance.

Described next, with reference to the figures, are exemplary embodiments of the power electronics device and the plug connector assembly.

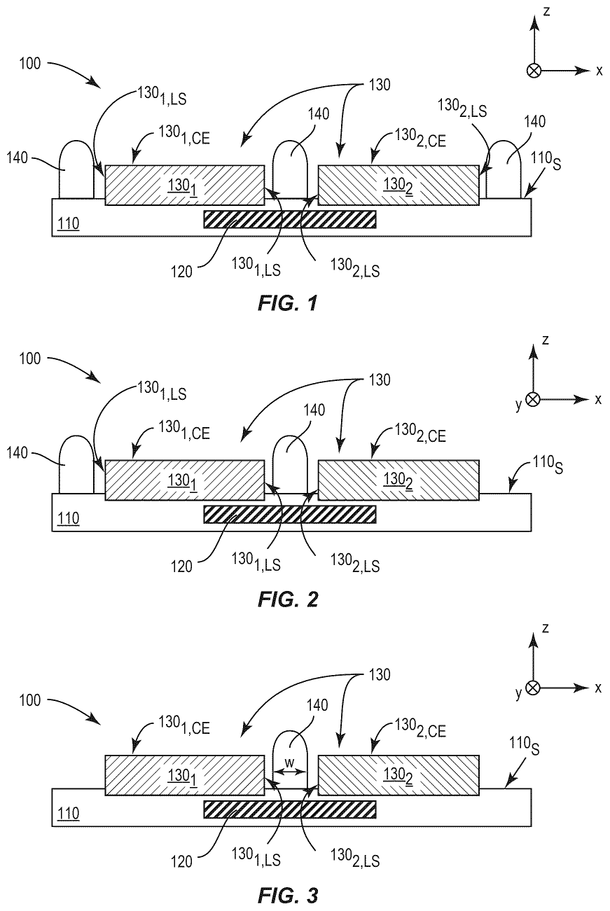

FIGS. 1-5 illustrate cross-sectional side views of a power electronics device 100, according to embodiments. The power electronics device 100 may be a power semiconductor module, component, or other packaged assembly. The power electronics device 100 includes one or more power semiconductor dies 120 within a housing 110. For illustrative purposes, a single power semiconductor die 120 is shown in FIGS. 1-5, although it should be understood that any of the examples of the power electronics device 100 described herein may include more than one power semiconductor die 120.

The power semiconductor die 120 may include one or more devices, e.g., one or more transistors, diodes, resistors, capacitors, and/or other types of active or passive devices. One or more of the power semiconductor dies 120 included in the power electronics device 100 may be a vertical power semiconductor die (e.g., a vertical power transistor die). For a vertical power transistor die, the primary current flow path is between the front and back sides of the power semiconductor die 120 (along the z direction in FIGS. 1-5). In one embodiment, one or more power semiconductor dies 120 are SiC transistor dies such as SiC power MOSFET (metal-oxide-semiconductor field-effect transistor) dies. One or more of the power semiconductor dies 120 included in the power electronics device 100 may be a Si power MOSFET die, HEMT (high-electron mobility transistor) die, IGBT (insulated-gate bipolar transistor) die, JFET (junction filed-effect transistor) die, etc. If more than one power semiconductor die 120 is included in the power electronics device 100, the power semiconductor dies 120 may all be of a similar or identical design (e.g., device type, structure, materials, dimensions, etc.), or some or each of the power semiconductor dies 120 may have different designs. Various arrangements of designs of power semiconductor dies 120 of the power electronics device 100 are contemplated. Each power semiconductor die 120 included in the power electronics device 100 and/or its constituent devices may be arranged to form all or part of a circuit of the power electronics device 100, such as a DC/AC inverter, a DC/DC converter, an AC/DC converter, a DC/AC converter, an AC/AC converter, a multi-phase inverter, an H-bridge, motor driver, etc. In some examples, the power electronics device 100 includes more than one power semiconductor die 120 and the circuit that includes the power semiconductor dies 120 is a half-bridge or full-bridge circuit.

The housing 110 of FIGS. 1-5 may be a frame enclosure. A frame enclosure may include one or more pieces of metal, plastic, composite, and/or other suitable material that is structured and arranged to enclose each power semiconductor die 120 included in the power electronics device 100. The walls and the top of the frame enclosure may be part of a single piece or may be separate pieces. For example, the top may be a lid. In some examples, a substrate on which the power semiconductor die(s) 120 are mounted forms a base of the enclosure. Examples of a substrate include a DCB (direct copper bonded) or AMB (active metal brazed) substrate, printed circuit board (PCB), lead frame, or other substrate, e.g., insulated metal substrate (IMS), etc.

The housing 110 of FIG. 1-5 may be a molded enclosure that is formed from a mold compound in which the power semiconductor die(s) 120 are embedded. A mold compound is a plastic encapsulant typically formed from an organic resin such as an epoxy resin. The plastic encapsulant may include fillers such as non-melting inorganic materials. Catalysts may be used to accelerate the cure reaction of the organic resin. Other materials such as flame retardants, adhesion promoters, ion traps, stress relievers, colorants, etc. may be added to the plastic encapsulant, as appropriate. The mold compound may be formed by injection molding, compression molding, film-assisted molding (FAM), reaction injection molding (RIM), resin transfer molding (RTM), blow molding, etc. In the example of a molded enclosure, the power semiconductor die(s) 120 may be mounted to a lead frame, PCB, or other substrate that is at least partly embedded in the mold compound.

The power electronics device 100 of FIGS. 1-5 includes a plurality of terminals 130 electrically connected to the one or more power semiconductor dies 120 included in the power electronics device 100. The plurality of terminals 130 may include terminals of one or more types, characterized, for example, by a type of contact end. Some examples include pin-type terminals, pads, tabs, clips, and screw-type terminals, among others.

A first terminal 130₁ and a second terminal 130₂ are shown in FIGS. 1-5 for illustrative purposes, although the plurality of terminals 130 may include more terminals 130 than those illustrated. The first terminal 130₁ and the second terminal 130₂ may, in some examples, be a DC+ and a DC− terminal, respectively. In some examples, one of the first terminal 130₁ and the second terminal 130₂ is a DC+ or DC-terminal and the other one of the first terminal 130₁ and the second terminal 130₂ is an AC terminal. For exemplary purposes, the first terminal 130₁ is configured for a higher electric potential and the second terminal 130₂ is configured for a lower electric potential than the first terminal 130₁, although it should be understood that this exemplary configuration is not so limiting and other configurations are contemplated. For example, the first terminal 130₁ may be configured for a lower electric potential than the second terminal 130₂. Additionally, each of the first terminal 130₁ and the second terminal 130₂ may be configured for a higher potential or lower potential than others of the plurality of terminals 130. Each of the first terminal 130₁ and the second terminal 130₂ has a contact end 130_{1,CE} and 130_{2,CE}, respectively, exposed and adjacent to one another at a side 110_{S} of the housing 100. The first terminal 130₁ and the second terminal 130₂ may be the same type (e.g., the same type of contact end) or may each be a different type.

According to the embodiments illustrated in FIGS. 1-5, an electrically insulative compressible body 140 is disposed along at least one lateral side, that is, a side facing in the x and/or y direction, of the contact end 130_{1,CE} of the first terminal 130₁ of the power electronics device 100. Examples of the compressible body 140 include a gasket, an o-ring, a wall, and a sleeve, among others. The compressible body 140 may be formed from any electrically insulative material having a high tensile strength, for example butyl rubber, ethylene-vinyl acetate (EVA), ethylene propylene diene terpolymer (EPDM), a fluoroelastomer (e.g., FPM, FKM), polyurethane, chloroprene rubber (CR), or various silicones. Some of these examples will be described in subsequent embodiments, but these examples are not limiting to the scope of this disclosure. The compressible body 140 may be attached to the housing 110 using an adhesive or glue, may be secured to a feature of the housing 110 such as a ridge, clip, divot, lip, or other feature of the housing 110 configured receive the compressible body 140, or may be attached or secured to the housing 110 by other means. For example, the compressible body 140 may be formed integrally with the housing 110 using a process such as two-component or multi-shot injection molding with liquid silicone rubber (LSR).

While the compressible body 140 of FIGS. 1-5 is illustrated and described with respect to the first terminal 130₁ and the second terminal 130₂, it should be understood that the compressible body 140, other equivalent compressible bodies 140, and/or additional similar compressible bodies 140 may be configured to isolate others of the plurality of terminals 130 of the power electronics device 100 that are not illustrated. Some such examples will be described later in this disclosure.

According to the embodiment of the power electronics device 100 illustrated in FIG. 1, the compressible body 140 (e.g., a gasket or sleeve) surrounds the contact end 130_{1,CE} of the first terminal 130₁ on all lateral sides 130_{1,LS} of the contact end 130_{1,CE} of the first terminal 130₁ and surrounds the contact end 130_{2,CE} of the second terminal 130₂ on all lateral sides 130_{2,LS} of the contact end 130_{2,CE} of the second terminal 130₂. In this example, the compressible body 140 is separated from both the first terminal 130₁ and the second terminal 130₂, although examples in which the compressible body 140 contacts one or both the first terminal 130₁ and the second terminal 130₂ are contemplated.

According to the embodiment of the power electronics device 100 illustrated in FIG. 2, the compressible body 140 surrounds the contact end 130_{1,CE} of the first terminal 130₁ on all lateral sides 130_{1,LS} of the contact end 130_{1,CE} of the first terminal 130₁. The compressible body 140 in this example of the power electronics device 100 may be an o-ring, a gasket, a sleeve, or another body. In this example, the compressible body 140 is separated from both the first terminal 130₁ and the second terminal 130₂, although examples in which the compressible body 140 contacts one or both the first terminal 130₁ and the second terminal 130₂ are contemplated.

According to the embodiment of the power electronics device 100 illustrated in FIG. 3, the compressible body 140 is a wall 140 disposed along a single lateral side 130_{1,LS} of the contact end 130_{1,CE} of the first terminal 130₁ and interposed between the contact end 130_{1,CE} of the first terminal 130₁ and the contact end 130_{2,CE} of a second terminal 130₂. In the installed state of the power electronics device 100 of FIG. 3, that is, when the wall 140 is compressed against a feature of an assembly or component such as a module, printed circuit board, busbar, etc., the creepage distance between the contact end 130_{1,CE} of the first terminal 130₁ and the contact end 130_{2,CE} of the second terminal 130₂ may be limited by a length of the wall 140 in the y direction and the width w of the wall 140 in the x direction. In this example, the wall 140 is separated from both the first terminal 130₁ and the second terminal 130₂, although examples in which the wall 140 contacts one or both the first terminal 130₁ and the second terminal 130₂ are contemplated.

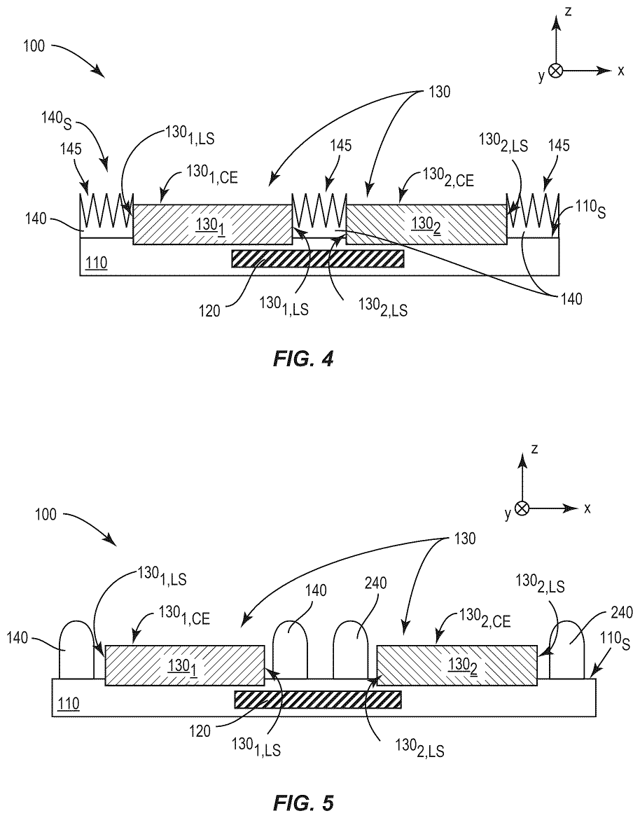

According to the embodiment of the power electronics device 100 illustrated in FIG. 4, the compressible body 140 (e.g., a gasket, a sleeve, o-ring, etc.) surrounds the contact end 130_{1,CE} of the first terminal 130₁ on all lateral sides 130_{1,LS} of the contact end 130_{1,CE} of the first terminal 130₁ and surrounds the contact end 130_{2,CE} of the second terminal 130₂ on all lateral sides 130_{2,LS} of the contact end 130_{2,CE} of the second terminal 130₂. In this example, the compressible body 140 is in contact with both the first terminal 130₁ and the second terminal 130₂, although examples in which the compressible body 140 is separated from one or both the first terminal 130₁ and the second terminal 130₂ are contemplated.

In the example of the power electronics device 100 of FIG. 4, the compressible body 140 includes a plurality of ridges 145 formed in a side 140_{S} of the compressible body 140 that faces away from the side 110_{S} of the housing 110. While the ridges 145 are only illustrated in the example of FIG. 4, other examples of the compressible body 140 described herein may include similar ridges and/or or other similar surface features.

In the example of the power electronics device 100 of FIG. 5, the compressible body 140 (e.g., a gasket, a sleeve, an o-ring) surrounds the contact end 130_{1,CE} of the first terminal 130₁ on all lateral sides 130_{1,LS} of the contact end 130_{1,CE} of the first terminal 130₁ and an additional electrically insulative compressible body 240 separate from the compressible body 140 (a separate gasket, sleeve, o-ring, etc.) surrounds the contact end 130_{2,CE} of the second terminal 130₂ on all lateral sides 130_{2,LS} of the contact end 130_{2,CE} of the second terminal 130₂. Like the compressible body 140, the additional compressible body 240 may be like the compressible body 140 of the example of FIG. 5 or of any of the other examples described herein in structure, material composition, shape, and/or other attributes. For example, the additional compressible body 240 may be a gasket, an o-ring, a sleeve, etc., formed from any electrically insulative material having a high tensile strength, for example butyl rubber, ethylene-vinyl acetate (EVA), ethylene propylene diene terpolymer (EPDM), a fluoroelastomer (e.g., FPM, FKM), polyurethane, chloroprene rubber (CR), or various silicones. In some examples, the compressible body 140 and the additional compressible body 240 are similar to one another (e.g., both may be gaskets, o-rings, formed the same material, etc.). In some examples, the compressible body 140 and the additional compressible body 240 are different from one another in type, shape, structure, material composition, etc. Methods for attaching or securing the additional compressible body 240 to housing 110 may be similar to those methods used for attaching or securing the compressible body 140 to the housing 110. Examples in which both the compressible body 140 and the additional compressible body 240 are formed integrally with the housing 110 are contemplated, for example using a process such as two-component or multi-shot injection molding with liquid silicone rubber (LSR).

While the example of FIG. 5 illustrates the additional compressible body 240 surrounding the contact end 130_{2,CE} of the second terminal 130₂ on all lateral sides 130_{2,LS}, examples in which the additional compressible body 240 is disposed along only one or some lateral sides 130_{2,LS} of the contact end 130_{2,CE} of the second terminal 130₂ are contemplated. For example, the additional compressible body 240 may be a wall 240 that is interposed between the compressible body 140 and a single lateral side 130_{2,LS} of the contact end 130_{2,CE} of a second terminal 130₂.

In the example of FIG. 5, the compressible body 140 and the additional compressible body 240 are both separated from the first terminal 130₁ and the second terminal 130₂, respectively, although examples in which one or both of the compressible body 140 and the additional compressible body 240 contact the first terminal 130₁ and the second terminal 130₂, respectively, are contemplated.

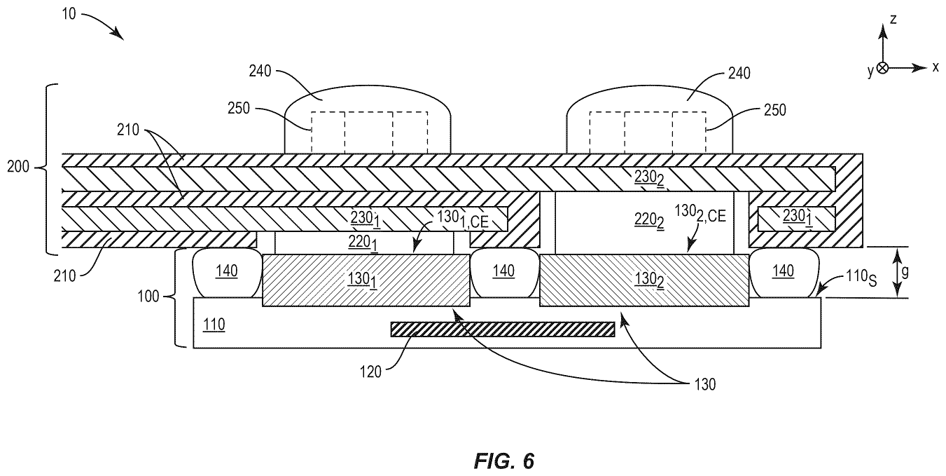

FIG. 6 illustrates a cross-sectional side view of an assembly 10 comprising the power electronics device 100, according to an embodiment. Specifically, the assembly 10 of FIG. 6 illustrates the power electronics device 100 in an installed state attached to a component 200 which, in this example, is a busbar 200. The busbar 200 may be configured to provide an interface between the power electronics device 100 and a capacitor bank, for example. Each of the first terminal 130₁ and the second terminal 130₂ of the power electronics device 100 is electrically coupled to a first conductor 230₁ and a second conductor 230₂, respectively, of the busbar 200. The first conductor 230₁ and the second conductor 230₂ of the busbar 200 are isolated from one another by insulators 210. Spacers 220₁ and 220₂ are disposed in openings in the insulators 210 of the busbar 200 and separate the first terminal 130₁ and the first conductor 230₁, and the second terminal 130₂ and the second conductor 230₂, respectively. Thus, the assembly includes a first conductive path that includes the first terminal 130₁, the spacer 220₁, and the first conductor 230₁, and a second conductive path that includes the second terminal 130₂, the spacer 220₂, and the second conductor 230₂. In this example, the first terminal 130₁ and the second terminal 130₂ are screw-type terminals and the busbar 200 is attached to the power electronics device 100 with screws 250, although other types or terminals and means of attachment are contemplated (e.g., pin-type terminals, soldering, welding, sintering). Each screw 250 may be coated with an electrically insulative coating 240 that is included to isolate the screws 250 from one another and further improve creepage and/or clearance performance.

The example of FIG. 6 specifically illustrates the power electronics component 100 of FIG. 1 in the installed state, although the description herein is applicable to any of the examples of the power electronics device 100 illustrated in FIGS. 1-5. In the installed state of the power electronics component 100 illustrated in FIG. 6, the compressible body 140 is configured to be under compression and sealed against the busbar 200, in this example against an insulator 210 of the busbar 200, and span a gap g between the side 110_{S} of the housing with the exposed terminals 130₁, 130₂ and the busbar 200.

The assembly 10 of FIG. 6 illustrates numerous advantages that may be provided by using the compressible body 140 described herein. On the side of the power electronics device 100, the compressible body 140 isolates the first terminal 130₁ and the second terminal 130₂ from one another, thus increasing the creepage distance between these terminals along surfaces of the power electronics component 100 and the busbar 200. On the side of the busbar 200, the compressible body 140, in its compressed, sealed state against the insulator 210, isolates the first conductor 230₁ and the spacer 220₁ from the second conductor 230₂ and the spacer 220₂, thus increasing the creepage distance between these different potential conductors along surfaces of the power electronics component 100 and the busbar 200. At the level of the assembly 10, the first conductive path that includes the first terminal 130₁, the spacer 220₁, and the first conductor 230₁, and the second conductive path that includes the second terminal 130₂, the spacer 220₂, and the second conductor 230₂, are isolated from one another. That is, the compressible body 140, in the compressed, installed state illustrated in FIG. 6, provides a seal on both the side of the power electronics device 100 and the side of the busbar 200 that face one another and thus is configured to entirely eliminate creepage pathways along surfaces of both the power electronics device 100 (e.g., between the terminals 130₁ and 130₂, between each terminal and any external points of varying potential or ground such as heatsinks or other mounting surfaces) and the busbar 200 of the assembly 10.

Furthermore, in examples in which the compressible body 140 surrounds one or both of the contact end 130_{1,CE} of the first terminal 130₁ or the contact end 130_{2,CE} of the second terminal 130₂ on all lateral sides, as in some of the examples of FIGS. 1-5, the compressible body 140 may seal one or both of the contact ends 130_{1,CE} and 130_{2,CE} from the outside environment, potentially reducing the impact of the cleanliness of the operating environment on creepage in the assembly 10 and, in some instances, reducing corrosion of the power electronics device 100 and/or the busbar 200 from outside contaminants, humidity, etc. Physically isolating the contact ends 130_{1,CE} and 130_{2,CE} from one another with the compressible body 140 (or, alternatively, separate compressible bodies 140 and/or additional compressible bodies 240) may also reduce risk of shorting between the first terminal 130₁ and the second terminal 130₂ from contaminants, broken or removed pieces of the power electronics device 100 or the component 200, etc.

The potential to improve creepage and/or clearance performance using the compressible body 140 in the manner illustrated in FIG. 6 may negate the need for complex features (e.g., fins, protrusions) on both the housing 110 of the power electronics device 100 and on the busbar 200, providing a potential cost savings by reducing manufacturing complexity. Additionally, eliminating the need for such features may also enable the assembly 10 to have a smaller profile, for example in the z direction.

Using the compressible body 140 as illustrated in FIG. 6 may enable the terminals 130 of the power electronics device 100, for example the terminals 130₁ and 130₂, to be placed closer to one another. In addition to the potential for enabling the power electronics device 100 to be smaller, placing the terminals 130 closer to one another may reduce stray inductance and enable operation at a higher voltage class, potentially improving switching speeds in the power electronics device 100.

While FIG. 6 illustrates the power electronics device 100 of FIG. 1 in the installed state, the features and advantages described herein are applicable to any of the examples of the power electronics device 100 described herein. For example, the features and advantages described herein are applicable to examples having one or more additional compressible bodies, for example the additional compressible body 240 of FIG. 5. Additionally, while the component 200 illustrated in FIG. 6 is a busbar, the features and advantages described herein are applicable to the power electronics device 100 in the installed state with other components 200 such as another power electronics device, a PCB, etc.

Described and illustrated hereafter are various exemplary implementations of the compressible body 140, the power electronics device 100, and, in some examples, the compressible body 140 and the power electronics device 100 in the installed state with the component 200.

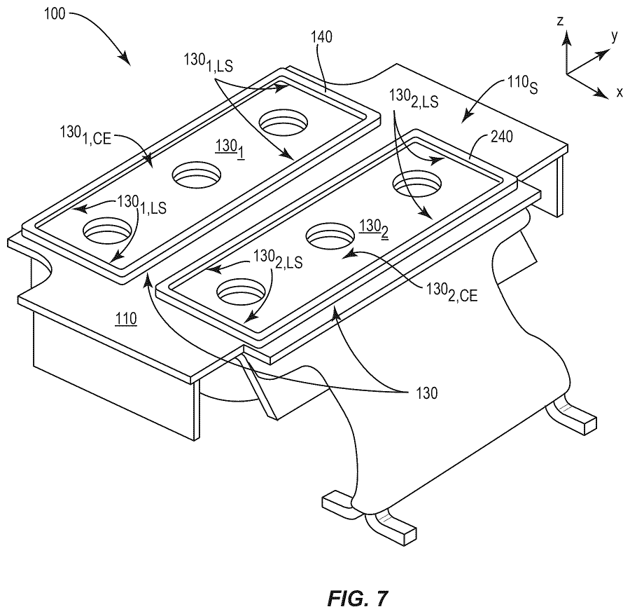

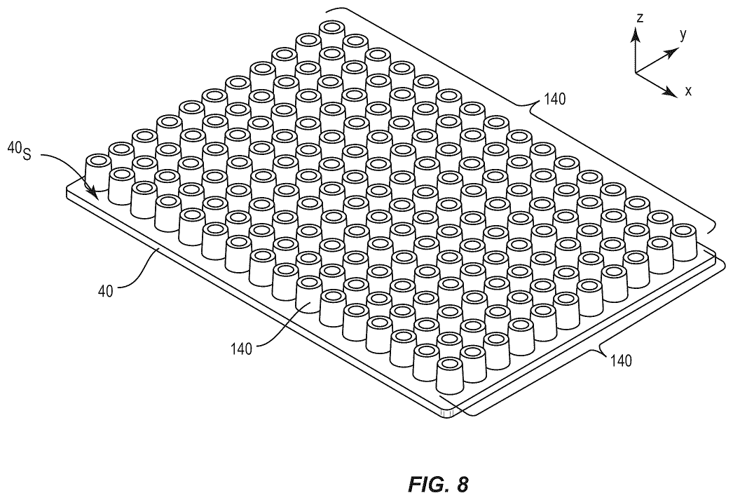

FIG. 7 illustrates a perspective view of the power electronics device 100, according to an embodiment. In this example, the housing 110 is a part of a frame enclosure. The first terminal 130₁ and the second terminal 130₂ of this example are screw-type terminals. The first terminal 130₁ and the second terminal 130₂ each have a contact end 130_{1,CE} and a contact end 130_{2,CE,} respectively, exposed at the surface 110ₛ of the housing 110.

The compressible body 140 and the additional compressible body 240 of this example are gaskets. The compressible body 140 surrounds the contact end 130_{1,CE} of the first terminal 130₁ on all lateral sides 130_{1,LS} of the contact end 130_{1,CE} of the first terminal 130₁. The additional compressible body 240 surrounds the contact end 130_{2,CE} of the second terminal 130₂ on all lateral sides 130_{2,LS} of the contact end 130_{2,CE} of the second terminal 130₂. The two separate compressible bodies 140, 240 instead may be replaced by a single gasket with two openings for receiving the contact ends 130_{1,CE} 130_{2,CE} of the terminals 130₁, 130₂.

FIG. 8 illustrates a perspective view of a plurality of the compressible bodies 140, according to an embodiment. In this example, each compressible body 140 is one of a plurality of sleeves 140 that is an integral part of a pad 40. Each sleeve 140 juts out from a surface 40_{S} of the pad 40 (in the z direction in this example). In some examples, the pad 40 and its integrated sleeves 140 are formed from a silicone. The silicone may be thermally resistant within an operating temperature range of the power electronics device 100 (e.g., up to 250°C.).

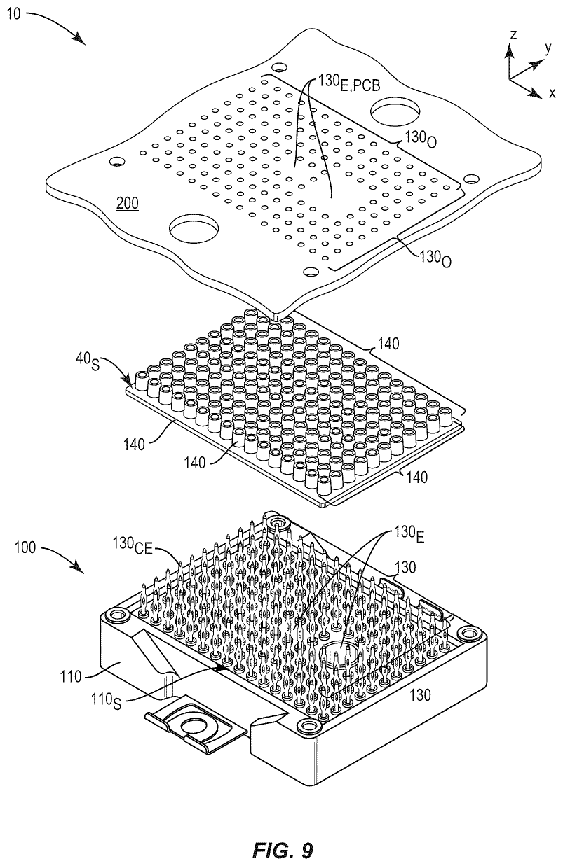

FIG. 9 illustrates an exploded perspective view of the assembly 10, comprising the power electronics device 100 and the pad 40 comprising the electrically insulative compressible sleeves 140, according to an embodiment.

In this example, the housing 110 is a frame enclosure. Each terminal 130 of the plurality of terminals 130 is a pin-type terminal 130. The contact end 130_{CE} of each pin-type terminal 130 is exposed from the side 110_{S} of the housing 110 and extends in the z direction from the side 110_{S}. Specifically, the contact end 130_{CE} of each pin-type terminal 130 extends through an opening in the side 110_{S} of the housing 110. The pin-type terminals 130 of this example are arranged in a grid on the side 110_{S}, although other arrangements of the pin-type terminals 130 contemplated. The side 110_{S} of the housing 110 includes empty regions 130_{E} in which there are no pin-type terminals 130. Other arrangements of the pin-type terminals 130 and one or more empty regions 130_{E} are contemplated.

The pad 40 is vertically aligned in the z direction with the power semiconductor device 100. The sleeves 140 of the pad 40 are arranged in a grid that corresponds to the grid layout of the pin-type terminals 130 on the side 110_{S} of the housing 110, including sleeves 140 in regions of the pad 40 that correspond to the empty regions. That is, the pad 40 includes an individual sleeve 140 for each one of the pin-type terminals 130 of the power electronics device 100, but may include additional sleeves 140 that do not correspond to a pin-type terminal 130. As will become clear in subsequent illustrations and descriptions, this distinction enables the pad 40 to be used for a variety of layouts of the pin-type terminals 130 (e.g., variations in placement of the pin-type terminals 130 and the empty regions 130_{E}), provided that the pin-type terminals 130 have the same general layout as the sleeves 140 on the pad 40.

The component 200, in this example, is a printed circuit board (PCB) 200, although component 200 could take the form of any kind of connector with conductive holes for pin insertion. The component 200 is vertically aligned in the z direction with the pad 40 and the power semiconductor device 100. The PCB 200 includes a plurality of openings 130_{O} each corresponding to a pin-type terminal 130 of the power semiconductor device 100, and empty regions 130_{E,PCB} PCB corresponding to the empty reg_{E}ons 130E on the sid_{S} 110S of the housing 110. Each opening 130_{O} of the PCB 200 may be configured to receive a corresponding pin-type terminal 130.

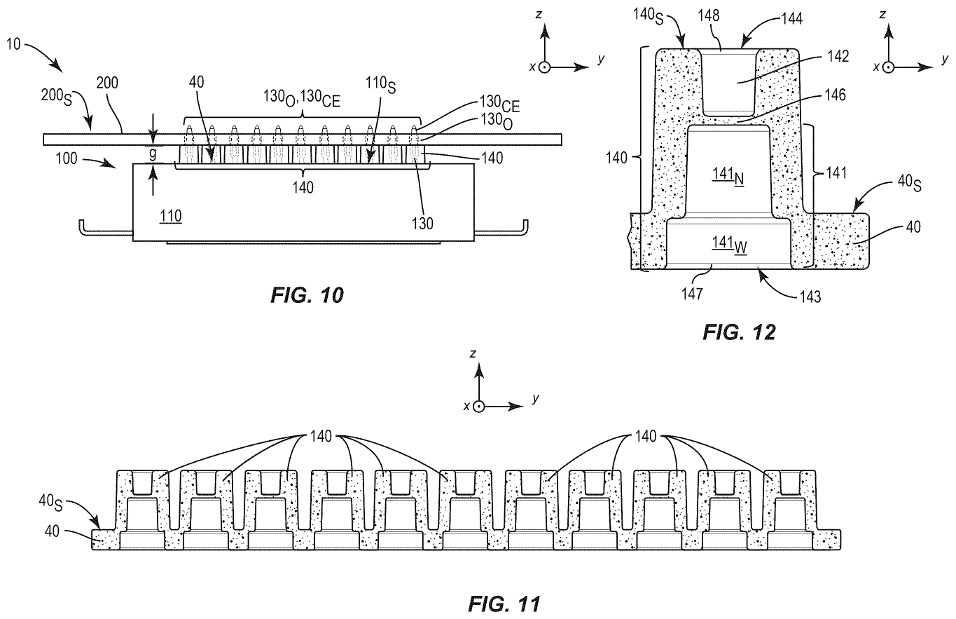

FIG. 10 illustrates a side view of the assembly 10, comprising the power electronics device 100 and the pad 40 comprising the electrically insulative compressible sleeves 140, according to an embodiment. Specifically, FIG. 10 illustrates the assembly 10 of FIG. 9 in the installed state of the power electronics device 100. In this state, the pad 40 is applied to the side 110_{S} of the housing 110 through which the pin-type terminals 130 protrude. The contact end 130_{CE} of each of the pin-type terminals 130 of the power electronics device 100 is inserted into and through a corresponding sleeve 140 of the pad 40 and into a corresponding opening 130_{O} of the PCB 200 such that a sleeve 140 surrounds the contact end 130_{CE} of each pin-type terminal 130 on all lateral sides of the contact end 130_{CE} of the pin-type terminal 130. In this example, a portion of each pin-type terminal 130, specifically a portion of each contact end 130_{CE}, may be exposed from a surface 200_{S} of the PCB 200 that faces away from the power electronics device 100. These portions of the pin-type terminals 130 may be soldered to the surface 200_{S} of the PCB 200, although this is only one example and other means of attaching the contact ends 130_{CE} of the pin-type terminals 130 to the PCB 200 are contemplated. For example, the pin-type terminals 130 of the power electronics device 100 may form press-fit connections with the openings 130_{O} of the PCB 200.

In the installed state illustrated in FIG. 10, each sleeve 140 of the pad 40 is configured to be under compression and span a gap g between the side 110_{S} of the housing 110 through which the pin-type terminals 130 protrude and the side of the PCB 200 that faces the power electronics device 100. The sleeves 140 are thus sealed to both the side 110_{S} of the housing 110 through which the pin-type terminals 130 protrude and the side of the PCB 200 that faces the power electronics device 100, potentially eliminating creepage pathways between the pin-type terminals 130 along surfaces of both the housing 110 and the PCB 200. Additionally, each sleeve 140 isolates a corresponding pin-type terminal 130 from the outside environment, potentially reducing the impact of cleanliness of the operating environment on creepage and reducing risk of shorting between pin-type terminals 130, as noted previously. Additionally, by sealing the pin-type terminals 130 and the side 110_{S} (e.g., sealing openings and surface of the side 110_{S} by applying the pad 40 to the side 110_{S}), both the sleeves 140 and the pad 40 may provide the power electronics device 100 with some protection against corrosion from chemicals, humidity, etc.

FIG. 11 illustrates a side view of the electrically insulative compressible sleeves 140 integrated into the pad 40, according to an embodiment. FIG. 12 illustrates a side view of an electrically insulative compressible sleeve 140 integrated into the pad 40, according to an embodiment. The orientations of the pad 40 and the sleeves 140 illustrated in FIGS. 11 and 12 are the same as those illustrated in FIG. 10, and thus some references may be made to various details and features of the pad 40 and the sleeves 140 of FIGS. 11 and 12 in relation to the side 110_{S}, the housing 110, and the power electronics device 100 of FIG. 10. That is, although the power electronics device 100 and the PCB 200 are omitted from FIGS. 11 and 12, some of the descriptions and illustrations of the pad 40 and the sleeves 140 may apply to the installed state of the power electronics device 100 illustrated in FIG. 10.

As noted previously, each sleeve 140 juts out from a surface 40_{S} of the pad 40 (in the z direction in this example). In this example, each sleeve 140 includes a first compartment 141 and a second compartment 142 aligned with the first compartment 141. In this example, a membrane 146 separates (i.e., closes off) the first compartment 141 and the second compartment 142 from one another. The first compartment 141 has a wider part 141_{W} that adjoins the side 110_{S} of the housing through which the pin-type terminals 130 protrude and a narrower part 141_{N} interposed between the wider part 141_{W} and the second compartment 142.

The first compartment 141 has an opening 143 that adjoins the side 110_{S} of the housing 110 through which the pin-type terminals 130 protrude. The second compartment 142 has an opening 144 at a side 140_{S} of the sleeve 140 that faces away from the side 110_{S} of the housing 110 through which the pin-type terminals 130 protrude. When applying the pad 40 to the side 110_{S} of the housing 110 through which the pin-type terminals 130 protrude, the contact end 130_{1,CE} of each pin-type terminal 130 is inserted into the opening 143 of the first compartment 141 of a corresponding sleeve 140. The wider part 141_{W} of the first compartment 141 may assist with aligning the contact end 130_{1,CE} with the corresponding sleeve 140. The membrane 146 of the corresponding sleeve 140 is punctured by the corresponding pin-type terminal 130 and the second compartment 142 receives part of the corresponding pin-type terminal 130 that is inserted into the opening 143 of the first compartment 141.

In the installed state of the power electronics device 100, a first lip 147 of each sleeve 140 forms a seal with the side 110_{S} of the housing 110 through which the pin-type terminals 130 protrude and a second lip 148 at the side 140_{S} of each sleeve 140 forms a seal with the PCB 200 (e.g., of FIG. 10) or other component 200 to which the contact ends 130_{CE} of the pin-type terminals 130 are connected. The second compartment 142 of one or more sleeves 140 may be configured as a solder reservoir to accommodate excess solder in the example where the contact end 130_{CE} of the corresponding pin-type terminal 130 is soldered to the PCB 200 or another component 200.

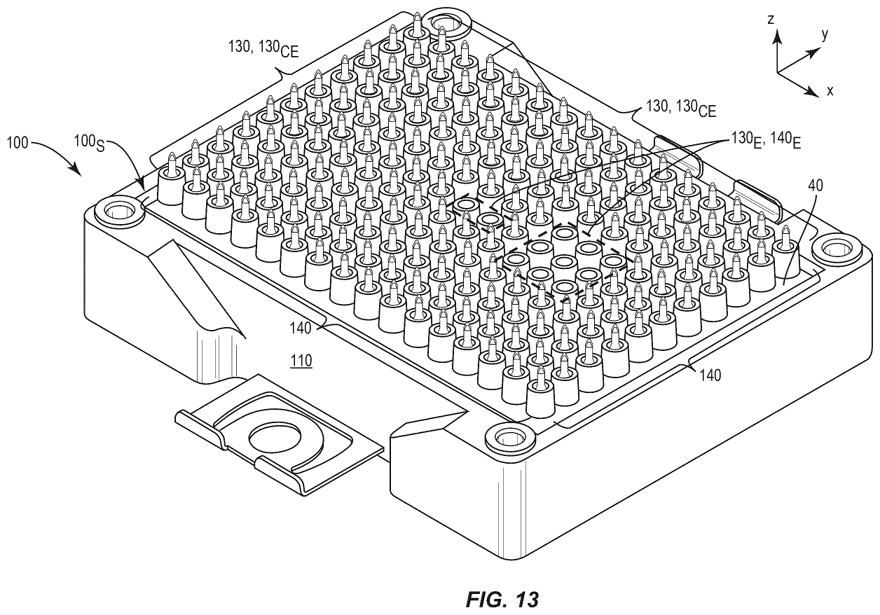

FIG. 13 illustrates a perspective view of the power electronics device 100 and the electrically insulative compressible sleeves 140 integrated into the pad 40, according to an embodiment. Specifically, FIG. 13 illustrates the power electronics device 100 after applying the pad 40 to the side 110_{S} of the housing 110 through which the pin-type terminals 130 protrude but before mounting of the power electronics component 100 in the installed state of the assembly 10. That is, in FIG. 13, the contact end 130_{CE} of each of the plurality of pin-type terminals 130 has been inserted into and through a corresponding sleeve 140 but the sleeves 140 are in the uncompressed state. In the uncompressed state of each sleeve 140, at least part of the contact end 130_{CE} of each pin-type terminal 130 protrudes from the sleeve 140.

FIG. 13 also identifies empty regions 130_{E} in which there are no pin-type terminals 130. In these empty regions 130_{E} there are corresponding empty sleeves 140_{E} through which no pin-type terminals 130 are inserted. The membrane 146 within these empty sleeves 140_{E} remains completely intact (i.e., unpenetrated) and thus the empty sleeves 140_{E} still provide a seal for each opening in the side 110_{S} of the power electronics device 100 through which no pin-type terminal 130 protrudes. This enables a common pad 40 to be used for variations of the power electronics device 100 with different layouts of the pin-type terminals 130, providing the benefits of the sleeves 140 without requiring customization of the layout of the sleeves 140 on the pad 40 for each layout of the pin-type terminals 130 while also sealing unused terminal openings in the housing 110.

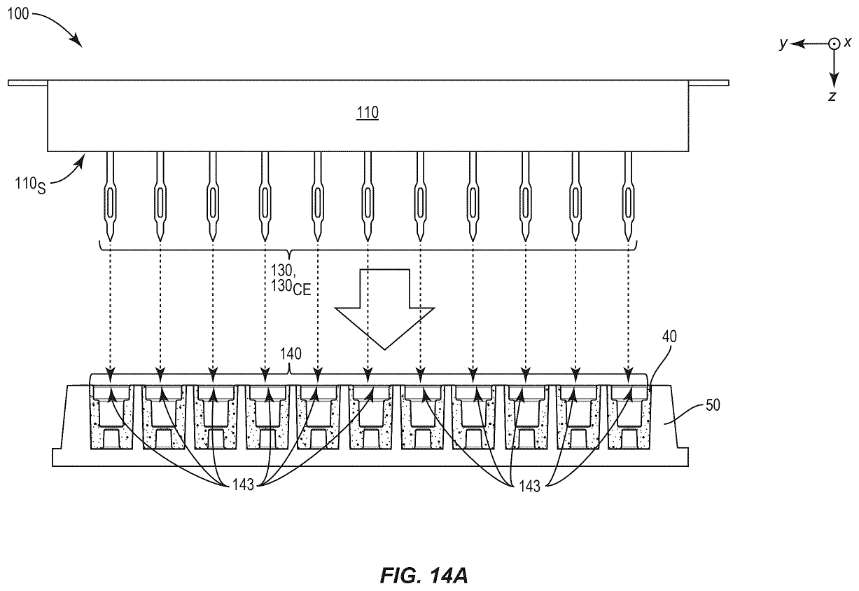

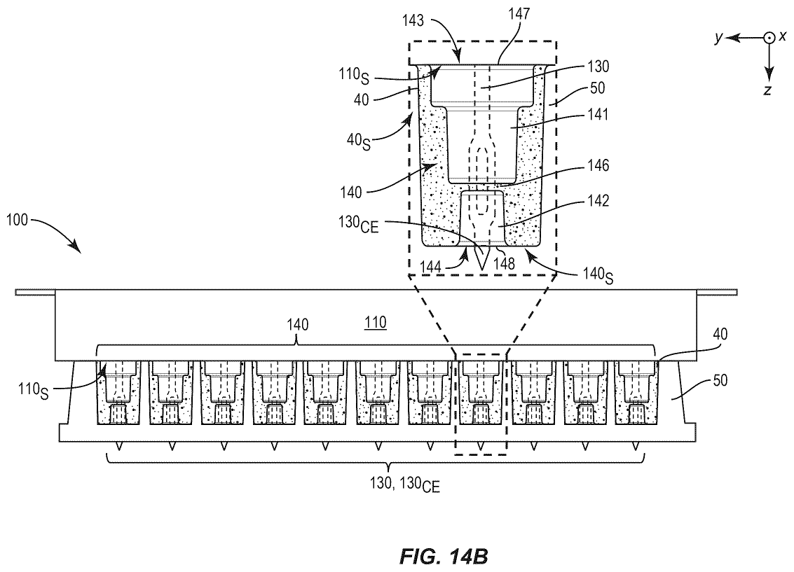

FIGS. 14A and 14B illustrate side views of fitting the electrically insulative compressible sleeves 140 on the pin-type terminals 130 of the power electronics device 100, according to an embodiment. It should be noted that the orientation of the power electronics device 100, the sleeves 140, and their respective features in FIGS. 14A and 14B are rotated by 180 degrees about the x axis relative to the previous figures.

FIG. 14A illustrates vertically aligning the power electronics device 100 and the sleeves 140 in the z direction. Specifically, the power electronics device 100 and the sleeves 140 are aligned such that the contact end 130_{CE} of each pin-type terminal 130 of the power electronics device 100 is vertically aligned in the z direction with the opening 143 of a corresponding sleeve 140. The vertical alignment illustrated in FIG. 14A may be enabled by securing individual sleeves 140 in an alignment jig 50 as illustrated.

FIG. 14B illustrates the contact end 130_{CE} of each of the pin-type terminals 130 inserted into and through a corresponding sleeve 140. The zoomed portion of FIG. 14B illustrates a pin-type terminal 130 inserted through the opening 143 of the first compartment 141, puncturing through the membrane 146, and inserted through the second compartment 142 such that a part of the contact end 130_{CE} of the pin-type terminal 130 protrudes from the opening 144 of sleeve 140. The first lip 147 of the sleeve 140 forms a seal with the side 110_{S} of the housing 110. While the sleeves 140 in FIG. 14B are not illustrated to be integrated into the pad 40 of previous examples, the illustration of the pin-type terminals 130 inserted into and through the corresponding sleeves 140 of FIG. 14B also applies to sleeves 140 that are integrated into the pad 40.

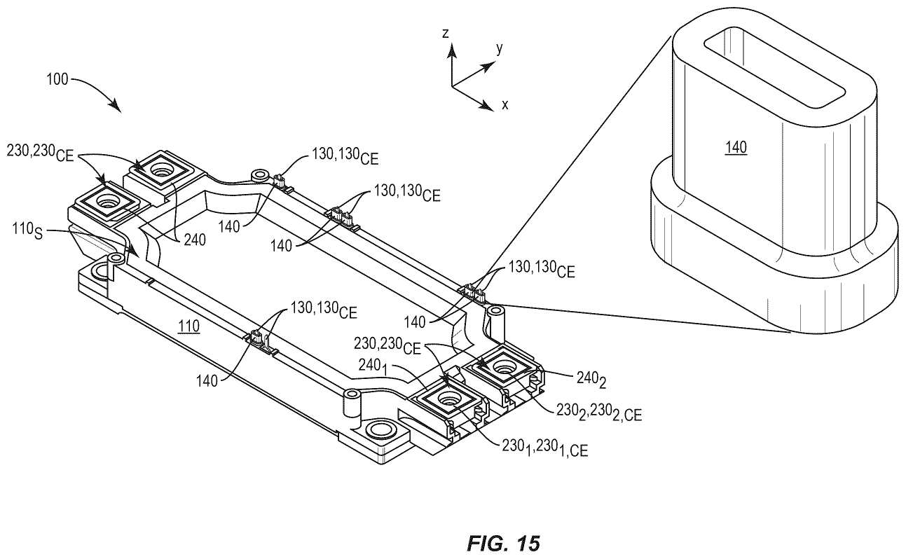

FIG. 15 illustrates a perspective view of the power electronics device 100, according to an embodiment. The power electronics device 100 of FIG. 15 includes a plurality of pin-type terminals 130 and a plurality of screw-terminals 230. The screw-type terminals 230 may be similar to the screw-type terminals 130 of FIG. 7 and are only referred to by a different reference numeral in FIG. 15 to distinguish them from the pin-type terminals 130. Each pin-type terminal 130 has a contact end 130_{CE} exposed at a side 110_{S} of the housing 110. Each screw-type terminal 230 has a contact end 230_{CE}. In this example, all of the contact ends 230_{CE} of the screw-type terminals 230 are exposed at the same side 110_{S} of the housing 110 as the contact ends 130_{CE} of the pin-type terminals 130, although examples in which some or all of the contact ends 230_{CE} are exposed at a different side of the housing 110 than the contact ends 130_{CE} of the pin-type terminals 130 are contemplated. The pin-type terminals 130 may be low-current and/or low-voltage terminals such as control terminals (e.g., for a gate of a power semiconductor die 120) or sense terminals (e.g., for current or temperature sensing). The screw-type terminals 230 may be power terminals (e.g., source, emitter, drain, collector, cathode, anode) designed to accommodate voltage and/or current levels that are incompatible with the pin-type terminals 130. In some examples, the power electronics device 100 is a medium voltage (MV) module.

The power electronics device 100 includes a plurality of electrically insulative compressible bodies 140 and a plurality of additional electrically insulative compressible bodies 240. In this example, the compressible bodies 140 are sleeves 140 and the additional compressible bodies 240 are gaskets 240. Other types of compressible bodies 140 and additional compressible bodies 240 are contemplated.

The contact end 130_{CE} of each of the pin-type terminals 130 is inserted into and through a corresponding sleeve 140 such that a sleeve 140 surrounds the contact end 130_{CE} of each pin-type terminal 130 on all lateral sides of the contact end 130_{CE} of the pin-type terminal 130. In the uncompressed state, as illustrated in FIG. 15, a part of the contact end 130_{CE} of each pin-type terminal 130 protrudes from the sleeve 140 through which the pin-type terminal 130 is inserted.

A gasket 240 is disposed along all lateral sides of the contact end 230_{CE} of each of the screw-type terminals 230. In this example, a separate gasket 240 is disposed along lateral sides of each contact end 230_{CE}, although examples in which a single gasket 240 is disposed along lateral sides of two or more contact ends 230_{CE} of screw-type terminals 230 are contemplated. As an example, a first gasket 240₁ surrounds the contact end 230_{1,CE} of a first screw-type terminal 230₁ on all lateral sides of the contact end 230_{1,CE} of the first screw-type terminal 230₁ and a second gasket 240₂ surrounds all lateral sides of a contact end 230_{2,CE} of a second screw-type terminal 230₂. The first screw-type terminal 230₁ may be configured for a first electric potential and the second screw-type terminal 230₂ may be configured for a second electric potential that is different than the first electric potential. More generally, the gaskets 240 may have any of the configurations shown in FIGS. 1 through 5.

In the installed state of the power electronics device 100, the sleeves 140 and the gaskets 240 (e.g., the first gasket 240₁ and the second gasket 240₂) are each configured to be under compression and span the gap g between the side 110_{S} of the housing 110 and the component 200 to which the contact ends 130_{CE} of the pin-type terminals 130 and the contact ends 230_{CE} of the screw-type terminals 230 are connected, e.g., in same the manner illustrated for the compressible body 140 and the busbar 200 in FIG. 6. The sleeves 140 and the gaskets 240 are thus each sealed to both the side 110_{S} of the housing 110 and a corresponding component 200 in the installed state, thereby eliminating creepage pathways between both the pin-type terminals 130 and the screw-type terminals 230 along surfaces of both the housing 110 and the corresponding component 200.

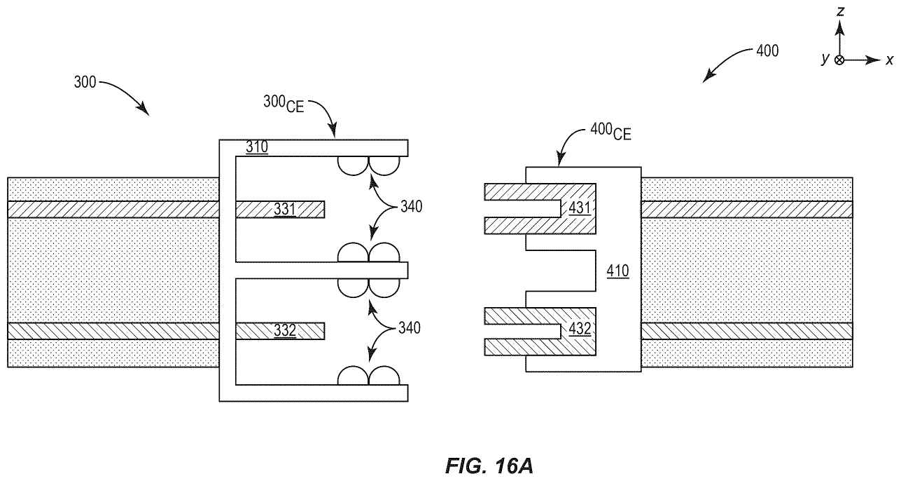

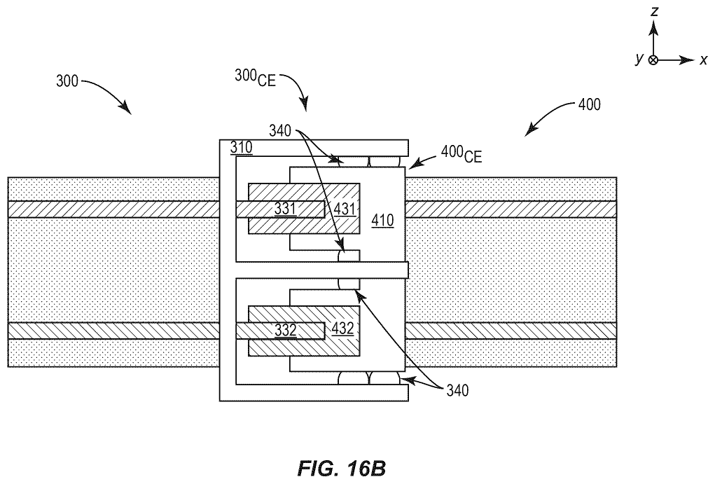

FIGS. 16A and 16B illustrate cross-sectional side views of a plug connector assembly 300 and a mating plug connector assembly 400, according to an embodiment. The plug connector assembly 300 may be configured as a connection for a power electronics module or other device, for example as a high voltage (HV) or medium voltage (MV) connection. The plug connector assembly 300 comprises a connection end 300_{CE} that includes an electrically insulative housing 310. The housing 310 houses a first exposed electrical conductor 331 configured for a first electric potential and a second exposed electrical conductor 332 configured for a second electric potential different than the first electric potential. For example, the first electric potential of the first exposed electrical conductor 331 may be a high potential and the second electric potential of the second exposed electrical conductor 332 may be a low potential, or vice versa. The mating plug connector assembly 400 includes a connection end 400_{CE} comprising an electrically insulative housing 410 that houses a first exposed electrical conductor 431 and a second exposed electrical conductor 432.

According to an embodiment, an electrically insulative compressible body 340 is attached to the electrically insulative housing 310 of the plug connector assembly 300 and/or to the electrically insulative housing 410 of the mating plug connector assembly 400. In FIG. 16A, the compressible body 340 is shown attached to the electrically insulative housing 310 of the plug connector assembly 300. However, the compressible body 340 instead may be attached to the electrically insulative housing 410 of the mating plug connector assembly 400 or divided into two parts with one part being attached to the electrically insulative housing 310 of the plug connector assembly 300 and the other part being attached to the electrically insulative housing 410 of the mating plug connector assembly 400.

In each case, the compressible body 340 may be formed from any electrically insulative material having a high tensile strength, for example butyl rubber, ethylene-vinyl acetate (EVA), ethylene propylene diene terpolymer (EPDM), a fluoroelastomer (e.g., FPM, FKM), polyurethane, chloroprene rubber (CR), or various silicones. The compressible body 340 may be attached to the respective housing 310, 410 using an adhesive or glue, may be secured to a feature of the housing 310 such as a ridge, clip, divot, lip, or other feature of the respective housing 310, 410 configured receive the compressible body 340, or may be attached or secured to the respective housing 310, 410 by other means. For example, the compressible body 340 may be formed integrally with the respective housing 310, 410 using a process such as two-component or multi-shot injection molding with liquid silicone rubber (LSR).

FIG. 16B illustrates the plug connector assembly 300 in a mated state with the mating plug connector assembly 400. In the mated state, the first exposed electrical conductor 331 of the plug connector assembly 300 couples to the first exposed electrical conductor 431 of the mating plug connector assembly 400 and the second exposed electrical conductor 332 of the plug connector assembly 300 couples to the second exposed electrical conductor 432 of the mating plug connector assembly 400. The compressible body 340 is configured to be under compression and forms a seal with the respective housing 410, 310 of the connection end 400_{CE} 300_{CE}, such that, inside the mated connection ends 300_{CE} and 400_{CE}, no creepage pathway is present between the first exposed electrical conductor 331 and the second exposed electrical conductor 332 of the plug connector assembly 300 and no creepage pathway is present between the first exposed electrical conductor 431 and the second exposed electrical conductor 432 of the mating plug connector assembly 400. That is, in this mated state, the compressible body 340 electrically and physically isolates the first and second exposed electrical conductors 331 and 332 of the plug connector assembly 300 from one another and from the outside environment and electrically and physically isolates the first and second exposed electrical conductors 431 and 432 of the mating plug connector assembly 400 from one another and from the outside environment, potentially eliminating the creepage pathway along the housings 310, 410 of both plug connector assemblies 300, 400, and eliminating the clearance pathway through the air between the exposed electrical conductors 331, 332, 431, and 432. While FIGS. 16A and 16B illustrate the plug connector assemblies 300, 400 as dual pole connector assemblies, the features described herein may be applied to other multipole connector or single pole connector assemblies. The compressible body 340 eliminates creepage pathways not only between the electrical conductors 331, 431 and 332, 432, but also between all electrical conductors 333, 332, 431, 432 and any external points of varying potential or ground such as heatsinks or other mounting surfaces.

Although the present disclosure is not so limited, the following numbered examples demonstrate one or more aspects of the disclosure.

Example 1. A power electronics device, comprising: a housing; one or more power semiconductor dies within the housing; a plurality of terminals electrically connected to the one or more power semiconductor dies and each having a contact end exposed at a side of the housing, wherein a first terminal is configured for a higher electric potential than other ones of the terminals; and a compressible body that is electrically insulative and disposed along at least one lateral side of the contact end of the first terminal, wherein for an installed state of the power electronics device, the compressible body is configured to be under compression and span a gap between the side of the housing at which the contact end of the first terminal is exposed and a component to which the contact end of the first terminal is to be connected.

Example 2. The power electronics device of example 1, wherein the compressible body is a gasket that surrounds the contact end of the first terminal on all lateral sides of the contact end of the first terminal.

Example 3. The power electronics device of example 2, wherein the contact end of the first terminal is adjacent to a contact end of a second terminal that is exposed at the same side of the housing as the contact end of the first terminal, wherein the second terminal is configured for a lower electric potential than the first terminal, and wherein the gasket surrounds the contact end of the second terminal on all lateral sides of the contact end of the second terminal.

Example 4. The power electronics device of example 1, wherein the compressible body is a wall disposed along a single lateral side of the contact end of the first terminal.

Example 5. The power electronics device of example 4, wherein the wall is interposed between the contact end of the first terminal and an adjacent contact end of a second terminal that is exposed at the same side of the housing as the contact end of the first terminal, wherein the second terminal is configured for a lower electric potential than the first terminal, and wherein for the installed state of the power electronics device, a creepage distance between the contact end of the first terminal and the contact end of the second terminal is limited by a length of the wall.

Example 6. The power electronics device of any of examples 1 through 5, wherein a plurality of ridges is formed in a side of the compressible body that faces away from the side of the housing at which the contact end of the first terminal is exposed.

Example 7. The power electronics device of any of examples 1 through 6, further comprising: an additional compressible body that is electrically insulative and disposed along at least one lateral side of a contact end of a second terminal that is exposed at the same side of the housing as the contact end of the first terminal, wherein for the installed state of the power electronics device, the additional compressible body is configured to be under compression and span a gap between the side of the housing at which the contact end of the second terminal is exposed and a component to which the contact end of the second terminal is to be connected.

Example 8. The power electronics device of example 7, wherein the compressible body is a first gasket that surrounds the contact end of the first terminal on all lateral sides of the contact end of the first terminal, and wherein the additional compressible body is a second gasket separate from the first gasket and that surrounds the contact end of the second terminal on all lateral sides of the contact end of the second terminal.

Example 9. The power electronics device of example 1, wherein the first terminal is a pin-type terminal, and wherein the compressible body is a sleeve into which the pin-type terminal is inserted.

Example 10. The power electronics device of example 9, wherein in an uncompressed state of the sleeve, at least part of the contact end of the pin-type terminal protrudes from the sleeve.

Example 11. The power electronics device of example 9 or 10, wherein for the installed state of the power electronics device, the sleeve is configured to be under compression and span a gap between the side of the housing at which the contact end of the first terminal is exposed and a component to which the contact end of the first terminal is to be connected.

Example 12. The power electronics device of any of examples 9 through 11, wherein the sleeve comprises: a first compartment having an opening that adjoins the side of the housing at which the contact end of the first terminal is exposed and into which the pin-type terminal is inserted; and a second compartment aligned with the first compartment and having an opening at a side of the sleeve that faces away from the side of the housing at which the contact end of the first terminal is exposed, the second compartment receiving part of the pin-type terminal.

Example 13. The power electronics device of example 12, wherein the sleeve further comprises a membrane separating the first compartment and the second compartment from one another, and wherein the membrane is punctured by the pin-type terminal.

Example 14. The power electronics device of example 12 or 13, wherein the second compartment is configured as a solder reservoir.

Example 15. The power electronics device of any of examples 12 through 14, wherein the first compartment has a wider part that adjoins the side of the housing at which the contact end of the first terminal and a narrower part interposed between the wider part and the second compartment.

Example 16. The power electronics device of any of examples 9 through 15, wherein the sleeve comprises: a first lip that forms a seal with the side of the housing at which the contact end of the first terminal is exposed; and a second lip at a side of the sleeve that faces away from the side of the housing at which the contact end of the first terminal is exposed, wherein for the installed state of the power electronics device, the second lip of the sleeve is configured to form a seal with the component to which the contact end of the first terminal is to be connected.

Example 17. The power electronics device of any of examples 9 through 16, wherein the sleeve is an integral part of a pad applied to the side of the housing at which the contact end of the first terminal is exposed, and wherein the sleeve juts out from a surface of the pad that faces away from the side of the housing at which the contact end of the first terminal is exposed.

Example 18. The power electronics device of example 17, wherein each terminal of the plurality of terminals is a pin-type terminal, and wherein the pad comprises an individual sleeve for each one of the pin-type terminals and into which the corresponding pin-type terminal is inserted.

Example 19. The power electronics device of example 18, wherein for the installed state of the power electronics device, each of the sleeves is configured to be under compression and span a gap between the side of the housing at which the contact end of the pin-type terminals are exposed and a component to which the contact end of the pin-type terminals are to be connected.

Example 20. The power electronics device of any of examples 9 through 19, further comprising: an additional compressible body that is electrically insulative and disposed along at least one lateral side of a contact end of a first screw-type terminal that is exposed at the same or different side of the housing as the contact end of the pin-type terminal, wherein for the installed state of the power electronics device, the additional compressible body is configured to be under compression and span a gap between the side of the housing at which the contact end of the first screw-type terminal is exposed and a component to which the contact end of the first screw-type terminal is to be connected.

Example 21. The power electronics device of example 20, wherein the additional compressible body is a first gasket that surrounds the contact end of the first screw-type terminal on all lateral sides of the contact end of the first screw-type terminal.

Example 22. The power electronics device of example 21, further comprising: a second gasket that is electrically insulative and surrounds all lateral sides of a contact end of a second screw-type terminal that is exposed at the same side of the housing as the contact end of the first screw-type terminal, wherein for the installed state of the power electronics device, the second gasket is configured to be under compression and span a gap between the side of the housing at which the contact end of the second screw-type terminal is exposed and a component to which the contact end of the second screw-type terminal is to be connected.

Example 23. A plug connector assembly, comprising: a connection end that comprises an electrically insulative housing that houses a first exposed electrical conductor configured for a first electric potential; and a compressible body that is electrically insulative and attached to the electrically insulative housing, wherein for a mated state of the plug connector assembly, the compressible body is configured to be under compression and form a seal with an electrically insulative housing of another connection end such that, inside the mated connection ends, no creepage pathway is present between the first exposed electrical conductor and a point of different potential or ground outside of the mated conduction ends.

Example 24. A plug connector assembly of example 23, wherein the electrically insulative housing of the connection end comprises a second exposed electrical conductor configured for a second electrical potential different than the first electrical potential, wherein for the mated state of the plug connector assembly, the compressible body is configured to be under compression and form a seal with an electrically insulative housing of another connection end such that, inside the mated connection ends, no creepage pathway is present between the first exposed electrical conductor and the second exposed electrical conductor.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power electronics device, comprising:
a housing;
one or more power semiconductor dies within the housing;
a plurality of terminals electrically connected to the one or more power semiconductor dies and each having a contact end exposed at a side of the housing, wherein a first terminal is configured for a higher electric potential than other ones of the terminals; and
a compressible body that is electrically insulative and disposed along at least one lateral side of the contact end of the first terminal,
wherein for an installed state of the power electronics device, the compressible body is configured to be under compression and span a gap between the side of the housing at which the contact end of the first terminal is exposed and a component to which the contact end of the first terminal is to be connected.

2. The power electronics device of claim 1, wherein the compressible body is a gasket that surrounds the contact end of the first terminal on all lateral sides of the contact end of the first terminal.

3. The power electronics device of claim 2, wherein the contact end of the first terminal is adjacent to a contact end of a second terminal that is exposed at the same side of the housing as the contact end of the first terminal, wherein the second terminal is configured for a lower electric potential than the first terminal, and wherein the gasket surrounds the contact end of the second terminal on all lateral sides of the contact end of the second terminal.

4. The power electronics device of claim 1, wherein the compressible body is a wall disposed along a single lateral side of the contact end of the first terminal.

5. The power electronics device of claim 4, wherein the wall is interposed between the contact end of the first terminal and an adjacent contact end of a second terminal that is exposed at the same side of the housing as the contact end of the first terminal, wherein the second terminal is configured for a lower electric potential than the first terminal, and wherein for the installed state of the power electronics device, a creepage distance between the contact end of the first terminal and the contact end of the second terminal is limited by a length of the wall.

6. The power electronics device of claim 1, wherein a plurality of ridges is formed in a side of the compressible body that faces away from the side of the housing at which the contact end of the first terminal is exposed.

7. The power electronics device of claim 1, further comprising:
an additional compressible body that is electrically insulative and disposed along at least one lateral side of a contact end of a second terminal that is exposed at the same side of the housing as the contact end of the first terminal,
wherein for the installed state of the power electronics device, the additional compressible body is configured to be under compression and span a gap between the side of the housing at which the contact end of the second terminal is exposed and a component to which the contact end of the second terminal is to be connected.

8. The power electronics device of claim 7, wherein the compressible body is a first gasket that surrounds the contact end of the first terminal on all lateral sides of the contact end of the first terminal, and wherein the additional compressible body is a second gasket separate from the first gasket and that surrounds the contact end of the second terminal on all lateral sides of the contact end of the second terminal.

9. The power electronics device of claim 1, wherein the first terminal is a pin-type terminal, and wherein the compressible body is a sleeve into which the pin-type terminal is inserted.

10. The power electronics device of claim 9, wherein in an uncompressed state of the sleeve, at least part of the contact end of the pin-type terminal protrudes from the sleeve.

11. The power electronics device of claim 9, wherein for the installed state of the power electronics device, the sleeve is configured to be under compression and span a gap between the side of the housing at which the contact end of the first terminal is exposed and a component to which the contact end of the first terminal is to be connected.

12. The power electronics device of claim 9, wherein the sleeve comprises:
a first compartment having an opening that adjoins the side of the housing at which the contact end of the first terminal is exposed and into which the pin-type terminal is inserted; and
a second compartment aligned with the first compartment and having an opening at a side of the sleeve that faces away from the side of the housing at which the contact end of the first terminal is exposed, the second compartment receiving part of the pin-type terminal.

13. The power electronics device of claim 12, wherein the sleeve further comprises a membrane separating the first compartment and the second compartment from one another, and wherein the membrane is punctured by the pin-type terminal.

14. The power electronics device of claim 12, wherein the second compartment is configured as a solder reservoir.

15. The power electronics device of claim 12, wherein the first compartment has a wider part that adjoins the side of the housing at which the contact end of the first terminal and a narrower part interposed between the wider part and the second compartment.

16. The power electronics device of claim 9, wherein the sleeve comprises:
a first lip that forms a seal with the side of the housing at which the contact end of the first terminal is exposed; and
a second lip at a side of the sleeve that faces away from the side of the housing at which the contact end of the first terminal is exposed,
wherein for the installed state of the power electronics device, the second lip of the sleeve is configured to form a seal with the component to which the contact end of the first terminal is to be connected.

17. The power electronics device of claim 9, wherein the sleeve is an integral part of a pad applied to the side of the housing at which the contact end of the first terminal is exposed, and wherein the sleeve juts out from a surface of the pad that faces away from the side of the housing at which the contact end of the first terminal is exposed.

18. The power electronics device of claim 17, wherein each terminal of the plurality of terminals is a pin-type terminal, and wherein the pad comprises an individual sleeve for each one of the pin-type terminals and into which the corresponding pin-type terminal is inserted.

19. The power electronics device of claim 18, wherein for the installed state of the power electronics device, each of the sleeves is configured to be under compression and span a gap between the side of the housing at which the contact end of the pin-type terminals are exposed and a component to which the contact end of the pin-type terminals are to be connected.

20. The power electronics device of claim 9, further comprising:
an additional compressible body that is electrically insulative and disposed along at least one lateral side of a contact end of a first screw-type terminal that is exposed at the same or different side of the housing as the contact end of the pin-type terminal,
wherein for the installed state of the power electronics device, the additional compressible body is configured to be under compression and span a gap between the side of the housing at which the contact end of the first screw-type terminal is exposed and a component to which the contact end of the first screw-type terminal is to be connected.

21. The power electronics device of claim 20, wherein the additional compressible body is a first gasket that surrounds the contact end of the first screw-type terminal on all lateral sides of the contact end of the first screw-type terminal.

22. The power electronics device of claim 21, further comprising:
a second gasket that is electrically insulative and surrounds all lateral sides of a contact end of a second screw-type terminal that is exposed at the same side of the housing as the contact end of the first screw-type terminal,
wherein for the installed state of the power electronics device, the second gasket is configured to be under compression and span a gap between the side of the housing at which the contact end of the second screw-type terminal is exposed and
a component to which the contact end of the second screw-type terminal is to be connected.

23. A plug connector assembly, comprising:
a connection end that comprises an electrically insulative housing that houses a first exposed electrical conductor configured for a first electric potential; and
a compressible body that is electrically insulative and attached to the electrically insulative housing,
wherein for a mated state of the plug connector assembly, the compressible body is configured to be under compression and form a seal with an electrically insulative housing of another connection end such that, inside the mated connection ends, no creepage pathway is present between the first exposed electrical conductor and a point of different potential or ground outside of the mated conduction ends.

24. The plug connector assembly of claim 23, wherein:
the electrically insulative housing of the connection end comprises a second exposed electrical conductor configured for a second electrical potential different than the first electrical potential;
wherein for the mated state of the plug connector assembly, the compressible body is configured to be under compression and form a seal with an electrically insulative housing of another connection end such that, inside the mated connection ends, no creepage pathway is present between the first exposed electrical conductor and the second exposed electrical conductor.
